(19) United States
(12) Patent Application Publication
(10) Pub. No.: US 2010/0025790 A1
(43) Pub. Date: Feb. 4, 2010

(54) IMAGE SENSOR AND METHOD OF MANUFACTURING THE SAME

(76) Inventor: HOON JANG, Chungbuk (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/511,301

(22) Filed: Jul. 29, 2009

(30) Foreign Application Priority Data
Jul. 29, 2008 (KR) 10-2008-0074192

(51) Int. Cl. H01L 31/0232; H01L 31/18

(52) U.S. Cl. 257/432; 438/69; 257/E31.127; 257/E21.158

(57) ABSTRACT

Disclosed are an image sensor and a method of manufacturing the same. The image sensor includes a semiconductor substrate having first and second surfaces opposite to each other, an isolation layer defining an active region while extending from the first surface toward the second surface, a photodiode in the active region and extending from the first surface toward the second surface, a reflection part adjacent to the first surface and disposed corresponding to the photodiode, and a lens part adjacent to the second surface.

### CROSS-REFERENCE TO RELATED APPLICATION

This application claims the benefit under 35 U.S.C. §119 of Korean Patent Application No. 10-2008-0074192, filed Jul. 29, 2008, which is hereby incorporated by reference in its entirety.

### BACKGROUND

The present disclosure relates to an image sensor and a method of manufacturing the same.

Recently, CMOS image sensors have been spotlighted as next-generation image sensors. The CMOS image sensor is a device employing a switching mode to sequentially detect an output of each unit pixel by means of MOS transistors, in which the MOS transistors are formed on a semiconductor substrate corresponding to the unit pixels through a CMOS technology, and using peripheral devices, such as a controller and a signal processor. The CMOS image sensor includes a photodiode and the MOS transistor in each unit pixel, and sequentially detects electric signals of each unit pixel in a switching mode to realize images.

Since the CMOS image sensor is manufactured by utilizing CMOS techniques, it has an advantage of low power consumption. In addition, since a smaller number of photo-processing steps is required, the manufacturing process of the CMOS image sensor can be simplified. Further, since a controller, a signal processor, an analog/digital converter, and the like can be integrated on a CMOS image sensor chip, the CMOS image sensor can minimize the size of a product. Accordingly, the CMOS image sensor is widely applied to various fields including, but not limited to, digital still cameras, and digital video cameras.

### BRIEF SUMMARY

An embodiment of the present invention provides an image sensor capable of increasing sensing efficiency and inhibiting interference between neighboring pixels, and a method of manufacturing the same.

According to an embodiment, an image sensor includes a semiconductor substrate having first and second surfaces opposite to each other, an isolation layer defining an active region while extending from the first surface toward the second surface, a photodiode in the active region and extending from the first surface toward the second surface, a reflection part adjacent to the first surface corresponding to the photodiode, and a lens part adjacent to the second surface.

According to an embodiment, a method of manufacturing an image sensor includes preparing a semiconductor substrate formed with an active region defined by an isolation layer, forming a photodiode in the active region, forming a reflection part on the photodiode, forming a pixel circuit part on the semiconductor substrate, and forming a lens part below the semiconductor substrate.

According to an embodiment, an image sensor includes a semiconductor substrate, an isolation layer formed on the semiconductor substrate while defining an active region, a photodiode formed in the active region, a reflection part disposed on the semiconductor substrate while covering the photodiode, a pixel circuit part electrically connected to the photodiode, and disposed on the semiconductor substrate, a support substrate disposed on the pixel circuit part, and a lens part disposed below the semiconductor substrate.

An image sensor according to certain embodiments includes a reflection part so that light, which has passed through the photodiode from the outside, can be reflected to the photodiode.

According to an embodiment, the reflection part can be formed in contact with the photodiode, so that leakage light can be minimized between the reflection part and the photodiode. Accordingly, the image sensor according to an embodiment can inhibit neighboring pixels from interfering with each other due to the leakage light.

Particularly, in the case of a backside illumination image sensor, the reflection part can inhibit light that has passed through the photodiode from being reflected due to the metal interconnection and then being incident on a photodiode of a neighboring pixel.

In addition, the image sensor according to an embodiment can improve the area of the photodiode regardless of the locations of the metal interconnections.

Therefore, an image sensor according to an embodiment can increase the sensing efficiency and inhibit neighboring pixels from interfering with each other.

In addition, since the reflection part can be formed together with the gate electrode when the gate electrode is formed, an additional process for the reflection part is not required.

### BRIEF DESCRIPTION OF THE DRAWINGS

FIG. 1 is a circuit diagram of an image sensor according to one embodiment;

FIG. 2 is a plan view showing a layout of the image sensor of FIG. 1;

FIG. 3 is a cross-sectional view taken along line I-I′ of FIG. 2;

FIGS. 4A to 4E are cross-sectional views showing a method of manufacturing a CMOS image sensor according to an embodiment;

FIG. 5 is a plan view showing a layout of the CMOS image sensor according to another embodiment; and

FIG. 6 is a cross-sectional view taken along line II-II′ of FIG. 5.

### DETAILED DESCRIPTION

In the description of embodiments, it will be understood that, when a substrate, a pattern, a region, or a layer is referred to as being “on” or “under” another substrate, another pattern, another region, or another layer, it can be “directly” or “indirectly” on the other substrate, pattern, region, or layer, or one or more intervening layers may also be present. Further, the “on” or “under” of each layer may be determined based on the drawings. In addition, the thickness or size of layers shown in the drawings may be simplified or exaggerated for the purpose of clear explanation. In addition, the size of each element may be reduced or magnified from the real size thereof.

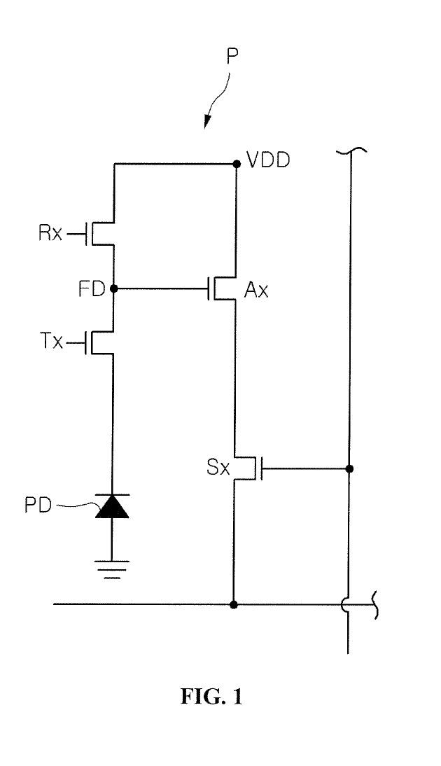

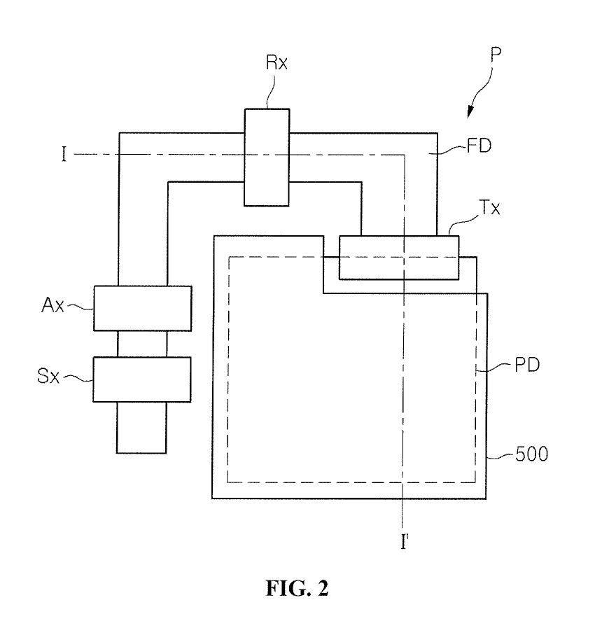

FIG. 1 is a circuit diagram showing an image sensor according to an embodiment. FIG. 2 is a plan view showing a layout of the image sensor of FIG. 1. FIG. 3 is a cross-sectional view taken along line I-I′ of FIG. 2.

Referring to FIGS. 1 and 2, a pixel P of an image sensor includes a photodiode PD to detect external light and a plurality of transistors to control the transfer and/or output of charges stored in the photodiode PD. According to the present embodiment, for example, the pixel P may include four transistors (4−Tr).

The pixel P includes the photodiode PD to detect light, a transfer transistor Tx, a reset transistor Rx, a select transistor Sx, and an access transistor Ax.

The photodiode PD is connected to the transfer transistor Tx and the reset transistor Rx in series. A source of the transfer transistor Tx is connected to the photodiode PD, and a drain 430 of the transfer transistor Tx is connected to a source of the reset transistor Rx. A supply voltage Vdd is applied to a drain of the reset transistor Rx.

The drain 430 of the transfer transistor Tx serves as a floating diffusion layer FD. The floating diffusion layer FD is connected to a gate of the select transistor Sx. The select transistor Sx is connected with the access transistor Ax in series. In other words, a source of the select transistor Sx is connected to the drain of the access transistor Ax. The supply voltage Vdd is applied to the drain of the access transistor Ax and the source of the reset transistor Rx. The drain of the select transistor Sx corresponds to an output terminal, and a select signal is applied to the gate of the select transistor Sx.

Hereinafter, the operation of the pixel P of the image sensor having the above structure will be described in brief. After the reset transistor Rx is turned on such that the floating diffusion layer FD has electric potential the same as that of the supply voltage Vdd, the reset transistor Rx is turned off. This operation is called a reset operation.

If external light is incident on the photodiode PD, electron-hole pairs (EHP) are generated in the photodiode PD so that signal charges are stored in the photodiode PD. Thereafter, as the transfer transistor Tx is turned on, the signal charges stored in the photodiode PD are output to the floating diffusion layer FD and stored in the floating diffusion layer FD. Accordingly, the electric potential of the floating diffusion layer FD is changed proportionally to quantity of the signal charges output from the photodiode PD, so that the electric potential of the gate of the access transistor Ax is changed. In this case, if the select transistor Sx is turned on by the select signal Row, data is output to the output terminal Out. After the data has been output, the pixel P carries out the reset operation. The pixel P repeats the above operation to convert light into an electric signal and output the electric signal.

Referring to FIG. 3, the CMOS image sensor includes a semiconductor substrate 100, an isolation layer 200, the photodiode PD, a pixel circuit part 400, a reflection part 500, a support substrate 600, and a lens part 700.

The semiconductor substrate 100 can be provided having a plate shape, and may be made of silicon. The semiconductor substrate 100 made thin enough for light to pass therethrough. The semiconductor substrate 100 has a top surface 101 and a bottom surface 102 opposite to each other.

The isolation layer 200 is formed on the top surface 101. In more detail, the isolation layer 200 extends from the top surface 101 towards the bottom surface 102. The isolation layer 200 may be formed through a shallow trench isolation (STI) process. The isolation layer 200 defines an active region AR and a non-active region (NR) of the semiconductor substrate 100.

The photodiode PD is formed on the semiconductor substrate 100. In more detail, the photodiode PD is formed in the active region AR. The photodiode PD extends from the top surface 101 towards the bottom surface 102.

The photodiode PD includes a region 310 doped with low concentration n-type impurities and a region 320 doped with low concentration p-type impurities.

The pixel circuit part 400 is formed on the semiconductor substrate 100. The pixel circuit part 400 is adjacent to the top surface 101. The pixel circuit part 400 includes transistors, insulating layers 441, 442, and 443, and metal interconnections.

The transistors include the transfer transistor Tx, the reset transistor Rx, the select transistor Sx, and the access transistor Ax. Among then, the transfer transistor Tx and the reset transistor Rx are shown in FIG. 3. The select transistor Sx and the access transistor Ax have a structure substantially identical to that of the transfer transistor Tx and the reset transistor Rx.

The transfer transistor Tx includes a gate electrode 410, spacers 420, and a drain 430.

The gate electrode 410 is disposed on the semiconductor substrate 100, and may be made of materials such as polysilicon and silicide. A gate insulating layer may be interposed between the gate electrode 410 and the semiconductor substrate 100.

The spacers 420 are disposed at side surfaces of the gate electrode 410. The spacers also may be disposed at side surfaces of the reflection part 500 (not shown in FIG. 3). The drain 430 is formed by implanting low-concentration and high-concentration impurities into the semiconductor substrate 100. The drain 430 serves as the floating diffusion layer FD.

The insulating layers 441, 442, and 443 are formed on the semiconductor substrate 100 while covering the transistors and the reflection part 500.

The metal interconnections 450 may be provided between the insulating layers 441, 442, and 443 and/or inside the insulating layers 441, 442, and 443. The metal interconnections 450 can be electrically connected to the gate electrode 410 and the drain 430.

The reflection part 500 is formed on the semiconductor substrate 100. The reflection part 500 is adjacent to the top surface 101 while corresponding to the photodiode PD. In as specific embodiment, the reflection pant 500 makes contact with the photodiode PD.

The reflection part 500 may be made of materials such as polysilicon and silicide. The reflection part 500 may be made of the same materials as those of the gate electrode 410 of the transistors.

For example, the reflection part 500 may include silicide.

In addition, the reflection part 500 can be disposed on a layer identical to that of the gate electrode 410 of the transistors.

The reflection part 500 covers the photodiode PD. The reflection part 500 has a plan area wider than that of the photodiode PD (see FIG. 2).

The reflection part 500 blocks light that has passed through the photodiode PD, and reflects the light to the photodiode PD.

The support substrate 600 is attached onto the pixel circuit part 400. The support substrate 600 supports the semiconductor substrate 100, the pixel circuit part 400, and the lens part 700.

The lens part 700 is disposed below the semiconductor substrate 100. In more detail, the lens part 700 is adjacent to the bottom surface 102. The lens part 700 includes a protective layer 710, a color filter 720, and a micro-lens 730.

The protective layer 710 is formed below the semiconductor substrate 100.

The color filter 720 is formed below the protective layer 720 to filter external light passing therethrough such that only light of specific color can pass through the color filter 720.

The micro-lens 730 is formed below the color filter 720 to condense external light and output the external light to the photodiode PD. The micro-lens 730 may be a convex lens having a convex curved surface.

External light is condensed on the micro-lens 730 and then incident onto the semiconductor substrate 100 through the bottom surface 102. The light that has been incident on the semiconductor substrate 100 is incident on the photodiode PD.

A portion of the light incident on the photodiode PD passes through the photodiode PD. The light that has passed through the photodiode PD is reflected by the reflection part 500 and then incident on the photodiode PD again.

Accordingly, the photodiode PD can convert a greater amount of light into signal charges, and the CMOS image sensor can effectively sense external light according to the embodiment.

Since the reflection part 500 is in contact with the photodiode PD, leakage current can be minimized between the reflection part 500 and the photodiode PD. Therefore, interference between neighboring pixels caused by the leakage current can be minimized in the CMOS image sensor according to this embodiment.

In particular, the reflection part 500 can inhibit light that has passed through the photodiode PD from being reflected from the metal interconnections 450 and then being incident on the photodiode of a neighboring pixel.

Therefore, the CMOS image sensor according to an embodiment can increase sensing efficiency and inhibit neighboring pixels from interfering with each other.

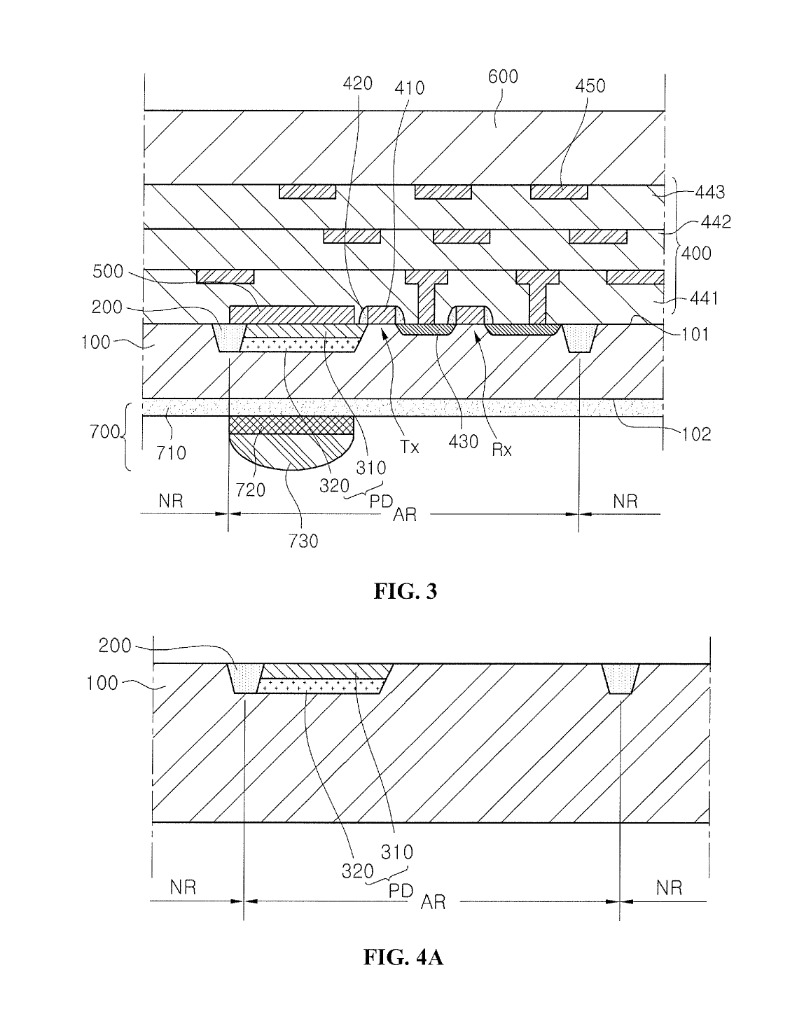

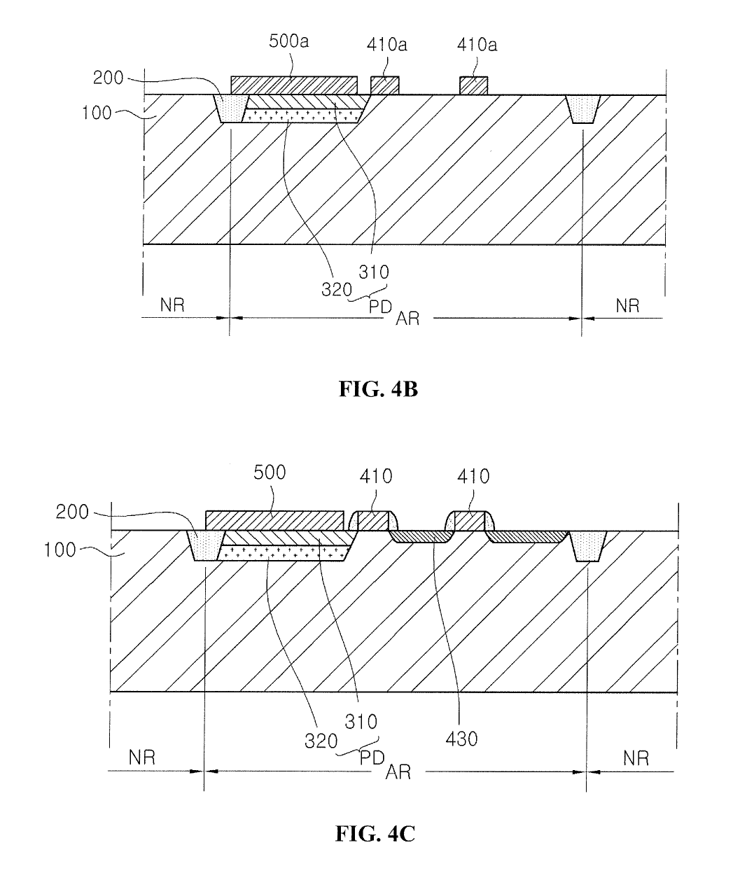

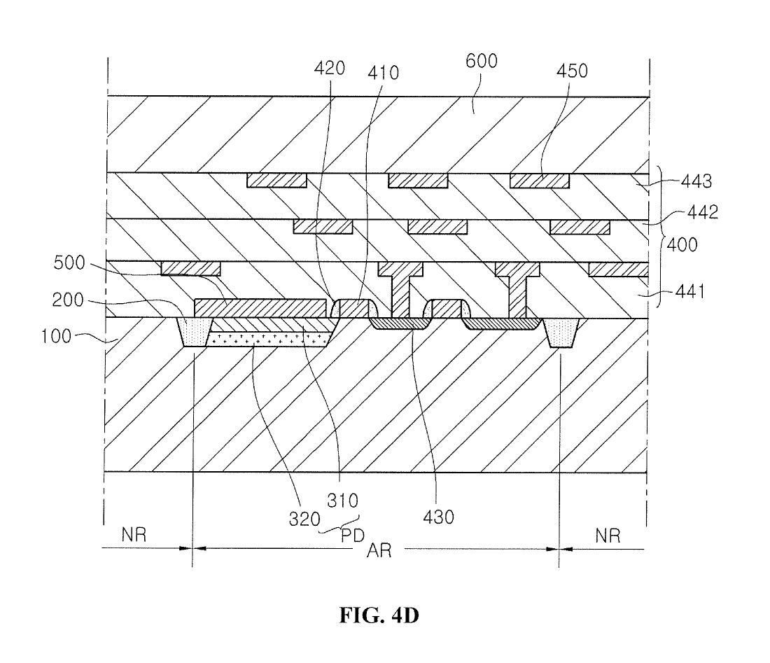

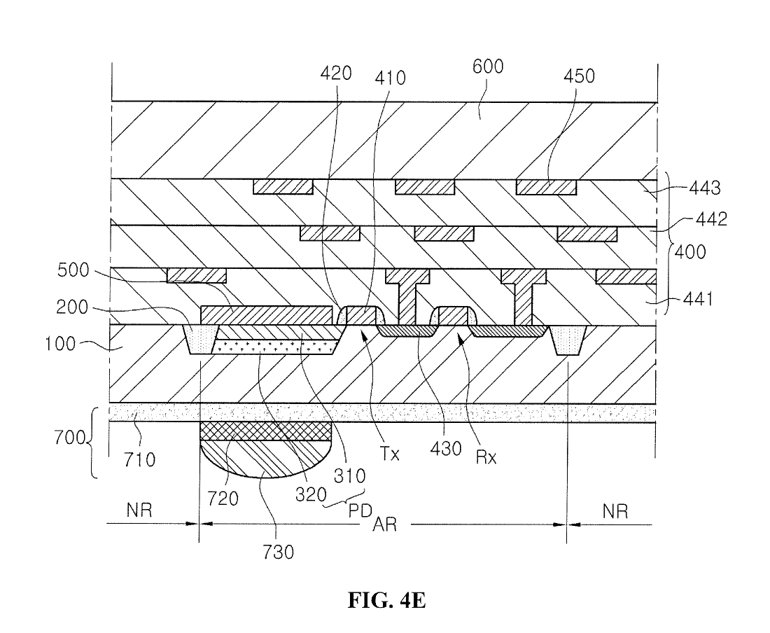

FIGS. 4A to 4E are cross-sectional views showing a method of manufacturing a CMOS image sensor according to an embodiment.

Referring to FIG. 4A, an isolation layer 200 is formed on a semiconductor substrate 100 through an STI process to define an active region AR and a non-active region NR on the semiconductor substrate 100.

Low concentration n-type impurities and low concentration p-type impurities are selectively implanted into the active region AR at different depths, thereby forming the photodiode diode PD including the region 310 doped with the low concentration n-type impurities and the region 320 doped with the low concentration p-type impurities.

Referring to FIG. 4B, after the photodiode PD has been formed, a polysilicon layer is formed on the semiconductor substrate 100. Thereafter, the polysilicon layer is patterned such that a preliminary reflection part 500a and a poly gate 410a are formed on the semiconductor substrate 100. A gate dielectric layer (not shown) may be formed before forming the polysilicon layer. In an embodiment, the gate dielectric layer may remain on the photodiode PD when forming the preliminary reflection part 500a. As shown in FIG. 2, the preliminary reflection part 500a covers the photodiode PD except for a region directly adjacent the transfer transistor Tx. The preliminary reflection part 500a has a plan area wider than that of the photodiode PD.

Referring to FIG. 4C, the spacers 420 are formed on the side surfaces of the poly gate 410a. Thereafter, high concentration n-type impurities are selectively implanted into the resultant structure so that the source and drain regions including region 430 are formed.

Next, a metal layer (not shown) is formed on the preliminary reflection part 500a and the poly gate 410a, and reacts with the preliminary reflection part 500a and the poly gate 410a through a heat treatment process.

Therefore, the reflection part 500 and the gate electrode 410 made of silicide are formed.

Referring to FIG. 4D, the insulating layers 441, 442, and 443 and metal interconnections are formed on the semiconductor substrate 100 over the transistors.

Thereafter, the support substrate 600 is attached to the uppermost insulating layer 443.

Referring to FIG. 4E, a lower portion of the semiconductor substrate 100 is ground so that the semiconductor substrate 100 has a thickness sufficient to allow light to pass therethrough. In one embodiment, the semiconductor substrate 100 is polished through a chemical mechanical polishing (CMP) process.

Next, after reversing (e.g., flipping) the semiconductor substrate 100, a protective layer 710, color filter 720, and micro-lens 730 can be formed on the semiconductor substrate 100.

Since the reflection part 500 is formed together with the gate electrode 410 when the gate electrode 410 is formed, the method of manufacturing a CMOS image sensor according to certain embodiments provides a CMOS image sensor having improved sensing efficiency without employing an additional mask process.

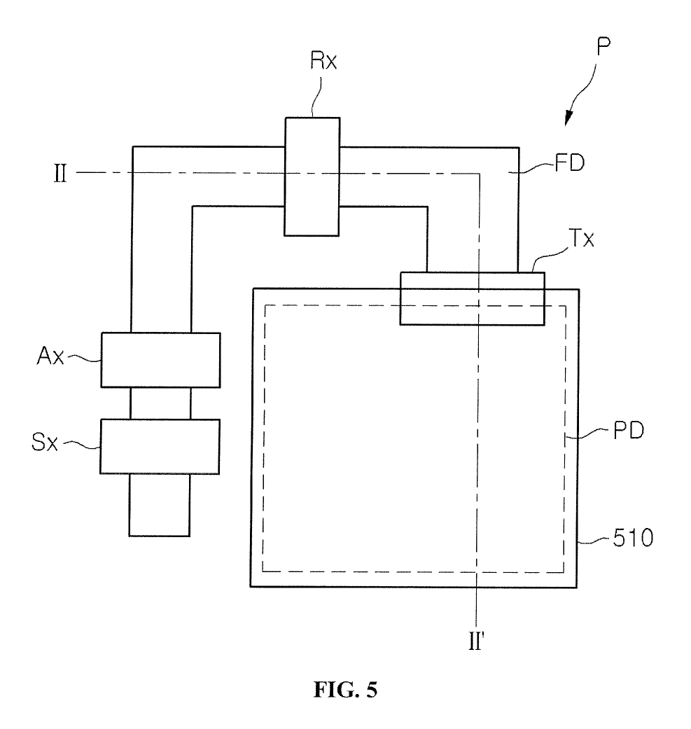

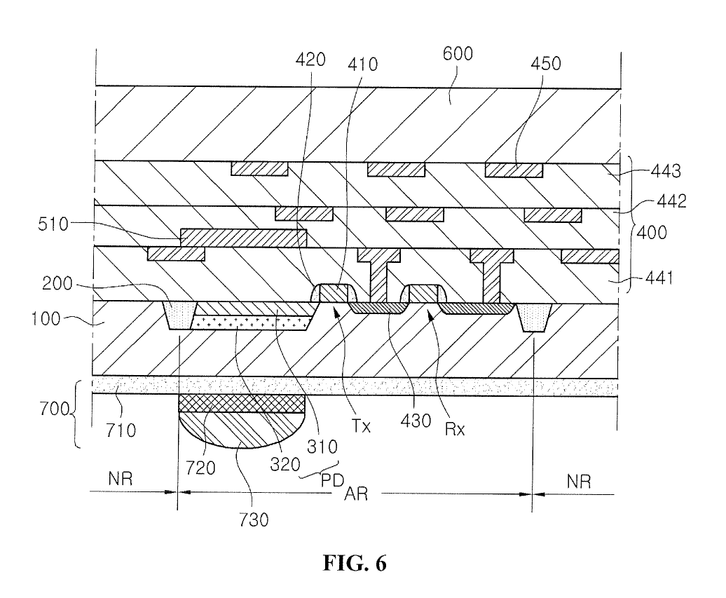

FIG. 5 is a plan view showing the layout of an image sensor according to another embodiment, and FIG. 6 is a cross-sectional view taken along line II-II′ of FIG. 5. In this embodiment, description will be made while focusing on the reflection part, and elements and structures described in the previous embodiment will not be further described in order to avoid redundancy.

Referring to FIGS. 5 and 6, the reflection part 510 is formed on the insulating layer 441 adjacent to the semiconductor substrate 100. In other words, the insulating layer 441 is interposed between the reflection part 510 and the semiconductor substrate 100.

The reflection part 510 covers the entire photodiode PD. The reflection part 510 is formed on a layer different from that of the gate electrode 410. That is, the reflection part 510 can cover a larger area without requiring consideration of the location of the gate electrode 410.

In detail, after transistors and the insulating layer 441 are formed on the semiconductor substrate 100, the reflection part 510 is formed on the resultant structure.

Accordingly, the reflection part 510 may be more widely formed regardless of the location of the gate electrode 410.

Different from FIGS. 5 and 6, in yet further embodiments, the reflection part 510 may be formed on the same layer as that of metal interconnections. The reflection part 510 may be made of materials the same as those of the metal interconnections. The reflection part may be formed together with the metal interconnections.

In more detail, the reflection part 510 may be made of the same material as that of the metal interconnections disposed on the first insulating layer 441, and formed on the same layer as that of the metal interconnections. In addition, the reflection part 510 may be formed on the first insulating layer 411.

Therefore, since the reflection part 510 can be formed in the process of forming the metal interconnection, an additional process to form the reflection part 510 is not required.

Accordingly, the reflection part 510 may be easily formed.

Therefore, the CMOS image sensor according to the present embodiment can effectively reflect light, which has passed through the photodiode PD, to the photodiode PD, so that external light can be effectively sensed.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate having first and second surfaces opposite to each other;
an isolation layer defining an active region while extending from the first surface toward the second surface;
a photodiode in the active region and extending from the first surface toward the second surface;
a reflection part adjacent to the first surface and disposed corresponding to the photodiode; and
a lens part adjacent to the second surface.

2. The image sensor of claim 1, further comprising:
a pixel circuit part adjacent to the first surface; and
a support substrate attached to the pixel circuit part.

3. The image sensor of claim 2, wherein the pixel circuit part includes a plurality of gate electrodes, and the reflection part is formed on a layer identical to a layer of the gate electrodes.

4. The image sensor of claim 1, wherein the reflection part includes polysilicon or silicide.

5. The image sensor of claim 1, wherein the reflection part covers the photodiode.

6. The image sensor of claim 1, wherein the reflection part has a plan area larger than a plan area of the photodiode.

7. The image sensor of claim 1, further comprising an insulating layer interposed between the reflection part and the photodiode.

8. A method of manufacturing an image sensor, the method comprising:
preparing a semiconductor substrate formed with an active region defined by an isolation layer;
forming a photodiode in the active region;
forming a reflection part on the photodiode;
forming a pixel circuit part on the semiconductor substrate; and
forming a lens part below the semiconductor substrate.

9. The method of claim 8, further comprising:
attaching a support substrate to the pixel circuit part; and
grinding a lower portion of the semiconductor substrate.

10. The method of claim 8, wherein the forming of the reflection part comprises:
forming a silicon layer on the photodiode; and
siliciding the silicon layer.

11. The method of claim 8, wherein the forming of the pixel circuit part comprises forming a gate electrode on the semiconductor substrate, wherein the gate electrode and the reflection part are formed simultaneously.

12. The method of claim 8, wherein the forming of the pixel circuit part comprises:
forming a gate electrode on the semiconductor substrate; and
forming an insulating layer, which covers the gate electrode, on the semiconductor substrate,
wherein the reflection part is formed on the insulating layer.

13. An image sensor comprising:
a semiconductor substrate;
an isolation layer formed on the semiconductor substrate while defining an active region;
a photodiode formed in the active region;
a reflection part disposed on the semiconductor substrate while covering the photodiode;
a pixel circuit part electrically connected to the photodiode, and disposed on the semiconductor substrate;
a support substrate disposed on the pixel circuit part; and
a lens part disposed below the semiconductor substrate.

14. The image sensor of claim 13, wherein the photodiode senses light passing through the lens part and the semiconductor substrate below the photodiode.

15. The image sensor of claim 13, wherein the reflection part makes direct contact with the photodiode.

16. The image sensor of claim 13, wherein the lens part comprises:
a protective layer disposed below the semiconductor substrate;
a color filter disposed below the protective layer; and
a micro-lens disposed below the color filter, the micro-lens having a curved surface.

17. The image sensor of claim 13, wherein the pixel circuit part comprises:
an insulating layer disposed on the semiconductor substrate; and
a metal interconnection disposed in the insulating layer,
wherein the reflection part is disposed on a layer identical to a layer of the metal interconnection, and wherein the reflection part includes a material identical to a material of the metal interconnection.
